(19) United States
(12) Patent Application Publication
(10) Pub. No.: US 2025/0159948 A1
(43) Pub. Date: May 15, 2025

(54) SPLIT SUPPORT SHIELD STRUCTURES FOR TRENCHED SEMICONDUCTOR DEVICES WITH INTEGRATED SCHOTTKY DIODES

(71) Applicant: Wolfspeed, Inc., Durham, NC (US)

(72) Inventors: Madankumar Sampath, Morrisville, NC (US); Woongsun Kim, Cary, NC (US); Naeem Islam, Morrisville, NC (US); Sei-Hyung Ryu, Cary, NC (US)

(21) Appl. No.: 18/508,322

(22) Filed: Nov. 14, 2023

(51) Int. Cl. H01L 29/06; H01L 21/04; H01L 29/16; H01L 29/66; H01L 29/78

(52) U.S. Cl. CPC H10D 62/111; H01L 21/0465; H10D 12/031; H10D 30/668; H10D 62/127; H10D 62/8325; H10D 84/146

(57) ABSTRACT

A power semiconductor device includes a semiconductor structure having a drift region of a first conductivity type. Gate trenches respectively comprising sidewalls and a bottom surface therebetween extend in a first direction in the semiconductor structure, and support shielding structures of a second conductivity type extend in the first direction in the semiconductor structure spaced apart from the sidewalls of the gate trenches. At least two of the support shielding structures are between immediately adjacent pairs of the gate trenches, or at least two of the gate trenches are between immediately adjacent pairs of the support shielding structures. For example, the support shielding structures may include first and second support shielding structures that are free of the gate trenches therebetween, or the gate trenches may include first and second gate trenches that are free of the support shielding structures therebetween. Related devices and fabrication methods are also discussed.

### FIELD

The present disclosure relates to semiconductor devices and, more particularly, to power semiconductor devices.

### BACKGROUND

Power semiconductor devices refer to devices that include one or more “power” semiconductor die that are designed to carry large currents (e.g., tens or hundreds of Amps) and/or that are capable of blocking high voltages (e.g., hundreds, thousand or tens of thousands of volts). A wide variety of power semiconductor devices are known in the art including, for example, power Metal Insulator Semiconductor Field Effect Transistors (“MISFETs,” including Metal Oxide Semiconductor FETs (“MOSFETs”)), bipolar junction transistors (“BJTs”), Insulated Gate Bipolar Transistors (“IGBT”), Junction Barrier Schottky diodes, Gate Turn-Off Transistors (“GTO”), MOS-controlled thyristors, and various other devices. These power semiconductor devices are generally fabricated from wide bandgap semiconductor materials, for example, silicon carbide (“SiC”) or Group III nitride (e.g., gallium nitride (“GaN”))-based semiconductor materials. Herein, a wide bandgap semiconductor material refers to a semiconductor material having a bandgap greater than about 1.40 eV, for example, greater than about 2 eV.

A conventional power semiconductor device typically has a semiconductor substrate having a first conductivity type (e.g., a n-type substrate) on which an epitaxial layer structure having the first conductivity type (e.g., n-type) is formed. A portion of this epitaxial layer structure (which may comprise one or more separate layers) functions as a drift layer or drift region of the power semiconductor device. The device typically includes an “active region,” which includes one or more “unit cell” structures that have a junction, for example, a p-n junction. The active region may be formed on and/or in the drift region. The active region acts as a main junction for blocking voltage in the reverse bias direction and providing current flow in the forward bias direction. The power semiconductor device may also have an edge termination in a termination region that is adjacent the active region. One or more power semiconductor devices may be formed on the substrate, and each power semiconductor device will typically have its own edge termination. After the substrate is fully processed, the resultant structure may be diced to separate the individual edge-terminated power semiconductor devices.

Power semiconductor devices may have a unit cell configuration in which a large number of individual unit cell structures of the active region are electrically connected (e.g., in parallel) to function as a single power semiconductor device. In high power applications, such a power semiconductor device may include thousands or tens of thousands of unit cells implemented in a single chip or “die.” A die or chip may include a small block of semiconducting material or other substrate in which electronic circuit elements are fabricated.

Power semiconductor devices can have a lateral structure or a vertical structure. In a device having a lateral structure, the terminals of the device (e.g., the drain, gate and source terminals for a power MOSFET device) are on the same major surface (e.g., top or bottom) of a semiconductor structure. In contrast, in a device having a vertical structure, at least one terminal is provided on each major surface of the semiconductor structure (e.g., in a vertical MOSFET device, the source may be on the top surface of the semiconductor structure and the drain may be on the bottom surface of the semiconductor structure). The semiconductor structure may or may not include an underlying substrate. Herein, the term “semiconductor structure” refers to a structure that includes one or more semiconductor layers, including semiconductor substrates and/or semiconductor epitaxial layers.

Vertical power semiconductor devices, such as MOSFET or IGBT devices, can have a standard gate electrode design in which the gate electrode of the transistor is formed on top of the semiconductor structure or, alternatively, may have the gate electrode buried in a trench within the semiconductor structure. Devices having buried gate electrodes are typically referred to as gate trench devices. In a standard gate electrode design, the channel region of each unit cell transistor is horizontally disposed underneath the gate electrode. In contrast, in the gate trench design, the channel is vertically disposed. Gate trench devices may provide enhanced performance, but typically require more complex manufacturing processes.

Power semiconductor devices are designed to block (in the forward or reverse blocking state) or pass (in the forward operating state) large voltages and/or currents. For example, in the blocking state, a power semiconductor device may be designed to sustain hundreds or thousands of volts of electric potential. As the applied voltage approaches or passes the voltage level that the device is designed to block, non-trivial levels of current (referred to as leakage current) may begin to flow through the power semiconductor device. The blocking capability of the device may be a function of, among other things, the doping density/concentration and thickness of the drift region. Leakage currents may also arise for other reasons, such as failure of the edge termination and/or the primary junction of the device. If the voltage applied to the device is increased beyond the breakdown voltage to a critical level, the increasing electric field may result in an uncontrollable and undesirable runaway generation of charge carriers within the semiconductor device, leading to a condition known as avalanche breakdown.

Also, the relatively thin gate insulating layer (e.g., a gate oxide layer) that separates the gate electrode from the semiconductor structure can degrade when the gate insulating layer is subjected to high electric field levels, during either on-state (conducting) or off-state (blocking) operation. This degradation of the gate insulating layer may ultimately lead to breakdown of the gate insulating layer, at which point the gate electrode may short circuit to the semiconductor structure, which can destroy the device.

### SUMMARY

According to some embodiments, a power semiconductor device includes a semiconductor structure comprising a drift region of a first conductivity type; a plurality of gate trenches respectively comprising sidewalls and a bottom surface therebetween extending in a first direction in the semiconductor structure; and a plurality of support shielding structures of a second conductivity type extending in the first direction in the semiconductor structure and spaced apart from the sidewalls of the gate trenches. At least two of the support shielding structures are between immediately adjacent gate trenches (i.e., pairs of the gate trenches that are immediately adjacent one another), or at least two of the gate trenches are between immediately adjacent support shielding structures (i.e., pairs of the support shielding structures that are immediately adjacent one another). For example, the at least two of the support shielding structures may include first and second support shielding structures that are free of the gate trenches therebetween, or the at least two of the gate trenches may include first and second gate trenches that are free of the support shielding structures therebetween.

In some embodiments, the at least two of the support shielding structures are free of the gate trenches therebetween, and are spaced apart by a first distance that is less than a second distance between pairs of the support shielding structures having one or more of the gate trenches therebetween.

In some embodiments, the at least two of the gate trenches are free of the support shielding structures therebetween, and are spaced apart by a first distance that is less than a second distance between pairs of the gate trenches having one or more of the support shielding structures therebetween.

In some embodiments, a plurality of bottom shielding structures of the second conductivity type extend in the semiconductor structure in the first direction under the gate trenches, respectively. A plurality of bridge shielding structures of the second conductivity type extend in the semiconductor structure in a second direction, which crosses the first direction, to contact the bottom shielding structures.

In some embodiments, at least one of the support shielding structures or the bridge shielding structures comprises a plurality of discrete segments with respective spacings therebetween along a direction of extension thereof in the first direction or the second direction, respectively.

In some embodiments, the bridge shielding structures and the support shielding structures have respective widths and/or respective depths that are substantially equal. For example, the respective widths may be between about 0.1 and about 20 microns. The support shielding structures may extend into the drift region to respective depths that are beyond the bottom shielding structures.

In some embodiments, a metal contact provides a Schottky barrier with the semiconductor structure between a pair of the gate trenches.

In some embodiments, the metal contact may include a first metal layer that provides ohmic contacts with the support shielding structures and a second metal layer that provides the Schottky barrier with the semiconductor structure.

In some embodiments, the metal contact may be a single or continuous layer, and may include respective portions that locally provide the Schottky barrier with the semiconductor structure and ohmic contacts with the support shielding structures.

In some embodiments, the support shielding structures may be regions of the second conductivity type that are implanted in or deposited on the drift region. As such, in some embodiments, the support shielding structures may be a same material as the drift region. In other embodiments, the material composition of the support shielding structures may be different from that of the drift region. For example, the drift region may be a wide bandgap semiconductor material, and the at least one of the bottom shielding structure or the first and second support shielding structures comprises polysilicon, nickel oxide, gallium nitride, or gallium oxide.

In some embodiments, the support shielding structures and/or the gate trenches may have a linear, elliptical, or polygonal shape in plan view.

According to some embodiments, a semiconductor structure includes a drift region of a first conductivity type, a plurality of gate trenches extending in a first direction in the semiconductor structure and spaced apart in a second direction, and a plurality of support shielding structures of a second conductivity type extending in the first direction in the semiconductor structure and spaced apart from respective sidewalls of the gate trenches in the second direction. Immediately adjacent pairs of the support shielding structures having one or more of the gate trenches therebetween are spaced apart at a first pitch, and immediately adjacent pairs of the gate trenches having one or more of the support shielding structures therebetween are spaced apart at a second pitch that is different than the first pitch.

In some embodiments, at least two of the support shielding structures are free of the gate trenches therebetween and are spaced apart by a first distance that is less than the first pitch.

In some embodiments, at least two of the gate trenches are free of the support shielding structures therebetween and are spaced apart by a second distance that is less than the second pitch.

In some embodiments, a plurality of bottom shielding structures of the second conductivity type extend in the semiconductor structure in the first direction under the gate trenches, respectively.

In some embodiments, a plurality of bridge shielding structures of the second conductivity type extend in the semiconductor structure in a second direction, which crosses the first direction, to contact the bottom shielding structures.

In some embodiments, a metal contact provides a Schottky barrier with the semiconductor structure between a pair of the gate trenches. For example, the metal contact may include a first metal layer that provides ohmic contacts with the support shielding structures and a second metal layer that provides the Schottky barrier with the semiconductor structure. Alternatively, the metal contact may include respective portions that provide the Schottky barrier with the semiconductor structure and ohmic contacts with the support shielding structures.

According to some embodiments, a power semiconductor device includes a semiconductor structure comprising a drift region of a first conductivity type; first and second gate trenches extending in a first direction in the semiconductor structure; first and second support shielding structures of a second conductivity type extending in the first direction in the semiconductor structure and spaced apart from sidewalls of the gate trenches with portions of the semiconductor structure therebetween; and a metal contact providing a Schottky barrier with the semiconductor structure between the first and second gate trenches.

In some embodiments, the metal contact may include a first metal layer that provides ohmic contacts with the first and second support shielding structures, and a second metal layer that provides the Schottky barrier with the semiconductor structure.

In some embodiments, the metal contact may include a single or continuous layer having respective portions that locally provide the Schottky barrier with the semiconductor structure and ohmic contacts with the first and second support shielding structures.

In some embodiments, the first and second support shielding structures may be between the first and second gate trenches, or the first and second gate trenches may be between the first and second support shielding structures.

In some embodiments, the first and second gate trenches are immediately adjacent one another and are spaced apart by a first distance, and the first and second support shielding structures are immediately adjacent one another and are spaced apart by a second distance that is different from the first distance.

In some embodiments, first and second bottom shielding structures of the second conductivity type extend in the semiconductor structure in the first direction under the first and second gate trenches, respectively.

In some embodiments, at least one bridge shielding structure of the second conductivity type extends in the semiconductor structure in a second direction, which crosses the first direction, to contact the first and second bottom shielding structures.

According to some embodiments, a method of fabricating a power semiconductor device includes providing a semiconductor layer structure comprising a drift region of a first conductivity type; forming a first mask pattern on the semiconductor layer structure, the first mask pattern comprising respective first openings therein that are immediately adjacent and spaced apart by a first distance, forming support shielding structures of a second conductivity type extending in a first direction in the semiconductor structure using the first openings in the first mask pattern; forming a second mask pattern on the semiconductor layer structure, the second mask pattern comprising respective second openings therein that are immediately adjacent and spaced apart by a second distance that is different than the first distance; and forming gate trenches extending in the first direction in the semiconductor structure using the second openings in the second mask pattern, wherein the gate trenches are spaced apart from the support shielding structures.

In some embodiments, at least two of the support shielding structures may be between immediately adjacent pairs of the gate trenches, or at least two of the gate trenches may be between immediately adjacent pairs of the support shielding structures.

In some embodiments, the at least two of the support shielding structures, which are between the immediately adjacent pairs of the gate trenches, are spaced apart by a first distance that is less than a second distance between pairs of the support shielding structures having one or more of the gate trenches therebetween.

In some embodiments, the at least two of the gate trenches, which are between the immediately adjacent pairs of the support shielding structures, are spaced apart by a first distance that is less than a second distance between pairs of the gate trenches having one or more of the support shielding structures therebetween.

In some embodiments, a third mask pattern is formed on the semiconductor layer structure, the third mask pattern comprising respective third openings therein that are spaced apart by a third distance. Bridge shielding structures of the second conductivity type are formed extending in the semiconductor structure in a second direction, which crosses the first direction, using the third openings in the third mask pattern.

In some embodiments, the first openings and the third openings may have respective widths that are between about 0.1 and about 20 microns.

In some embodiments, the first openings and the third openings may have respective widths that are substantially equal.

In some embodiments, the bridge shielding structures and the support shielding structures may have respective depths that are substantially equal.

In some embodiments, the bridge shielding structures may have respective widths that are less than or equal to respective widths of the support shielding structures.

In some embodiments, at least one of the support shielding structures or the bridge shielding structures may include a plurality of discrete segments with respective spacings therebetween along a direction of extension thereof in the first direction or the second direction, respectively.

In some embodiments, a metal contact is formed to provide a Schottky barrier with the semiconductor structure between a pair of the gate trenches.

In some embodiments, the metal contact may be formed by forming a first metal layer that provides ohmic contacts with the support shielding structures and forming a second metal layer that provides the Schottky barrier with the semiconductor structure.

In some embodiments, the metal contact may be formed by forming a single or continuous metal layer comprising respective portions that provide the Schottky barrier with the semiconductor structure and ohmic contacts with the support shielding structures.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1A is a schematic cross-sectional view illustrating an example unit cell of a gate trench power semiconductor device including shielding regions positioned below the gate trenches.

FIG. 1B is a schematic cross-sectional view illustrating an example unit cell of a gate trench power semiconductor device including shielding regions that are positioned below and along one sidewall of the gate trenches.

FIG. 2A is a schematic cross-sectional view illustrating example unit cells of a gate trench power semiconductor device including multiple support shielding (or “split support shielding”) structures according to some embodiments of the present disclosure.

FIG. 2B is a schematic cross-sectional view illustrating example unit cells of a gate trench power semiconductor device including split support shielding structures and an integrated Schottky diode according to some embodiments of the present disclosure.

FIG. 3A is a schematic cross-sectional view illustrating example unit cells of a gate trench power semiconductor device including multiple gate (or “split gate”) structures according to some embodiments of the present disclosure.

FIG. 3B is a schematic cross-sectional view illustrating example unit cells of a gate trench power semiconductor device including split gate structures and an integrated Schottky diode according to some embodiments of the present disclosure.

FIG. 4A is a schematic cross-sectional view illustrating example unit cells of a gate trench power semiconductor device including split support shielding structures and split gate structures according to some embodiments of the present disclosure.

FIG. 4B is a schematic cross-sectional view illustrating example unit cells of a gate trench power semiconductor device including split support shielding structures, split gate structures, and an integrated Schottky diode according to some embodiments of the present disclosure.

FIG. 5A is a plan view illustrating a layout or pattern of split support shielding structures and gate trenches according to some embodiments of the present disclosure. FIGS. 5B and 5C are cross sectional views taken along lines B-B and C-C of FIG. 5A, respectively.

FIG. 6A is a plan view illustrating a layout or pattern of segmented split support shielding structures and gate trenches according to some embodiments of the present disclosure. FIGS. 6B, 6C, and 6D are cross sectional views taken along lines B-B, C-C, and D-D of FIG. 6A, respectively.

FIG. 7A is a plan view illustrating a layout or pattern of split support shielding structures, gate trenches, and integrated Schottky diodes according to some embodiments of the present disclosure. FIGS. 7B and 7C are cross sectional views taken along lines B-B and C-C of FIG. 7A, respectively.

FIG. 8A is a plan view illustrating a layout or pattern of segmented split support shielding structures, gate trenches, and integrated Schottky diodes according to some embodiments of the present disclosure. FIGS. 8B, 8C, and 8D are cross sectional views taken along lines B-B, C-C, and D-D of FIG. 8A, respectively.

FIGS. 9A, 9B, 9C, 9D, 9E, and 9F are schematic cross-sectional views illustrating example fabrication operations for forming power semiconductor devices including split support shielding structures and gate trenches according to some embodiments of the present disclosure.

FIGS. 10A and 10B are plan views illustrating patterns of split support shielding structures and segmented split support shielding structures, respectively, with square-shaped trenched gate electrodes according to some embodiments of the present disclosure.

FIGS. 11A and 11B are plan views illustrating patterns of split support shielding structures and segmented split support shielding structures, respectively, with hexagonal-shaped trenched gate electrodes according to some embodiments of the present disclosure.

### DETAILED DESCRIPTION OF EMBODIMENTS

Some embodiments of the present invention are directed to improvements in power semiconductor devices (e.g., MOSFETs, IGBTs, and other gate controlled power devices). In devices having gate electrodes and gate insulating layers formed within trenches in the semiconductor structure, high electric fields may degrade the gate insulating layer over time, and may eventually result in failure of the device. Deep shielding structures (also referred to herein as bottom shielding structures) may be provided underneath the gate trenches in order to reduce the electric field levels in the gate insulating layer, particularly at corners of the gate trenches where the electric field levels may be more concentrated. The bottom shielding structures may have the same conductivity type as the well regions, which is opposite the conductivity type of the drift region.

The bottom shielding structures may typically include highly doped semiconductor regions having the same conductivity type as the channel region. Methods for doping a semiconductor material with n-type and/or p-type dopants include (1) doping the semiconductor material during the growth thereof, (2) diffusing the dopants into the semiconductor material and (3) using ion implantation to selectively implant the dopants in the semiconductor material. When silicon carbide is doped during epitaxial growth, the dopants tend to unevenly accumulate, and hence the dopant concentration may vary by, for example, +/−15%, which can negatively affect device operation and/or reliability. Additionally, doping by diffusion may not be an option in silicon carbide, gallium nitride and various wide band-gap semiconductor devices since n-type and p-type dopants tend to not diffuse well (or at all) in those materials, even at high temperatures.

In light of the above, ion implantation is often used to dope wide band-gap semiconductor materials, such as silicon carbide. The depth at which the ions are implanted is directly related to the energy of the implant, i.e., ions implanted into a semiconductor layer at higher energies tend to go deeper into the layer. However, when dopant ions are implanted into a semiconductor layer, the ions damage the crystal lattice of the semiconductor layer. This lattice damage can typically only be partly repaired by thermal annealing processes. The amount of lattice damage may also be directly related to the implant energy, with higher energy implants tending to cause more lattice damage than lower energy implants. The uniformity of the dopant concentration also tends to decrease with increasing implant depth.

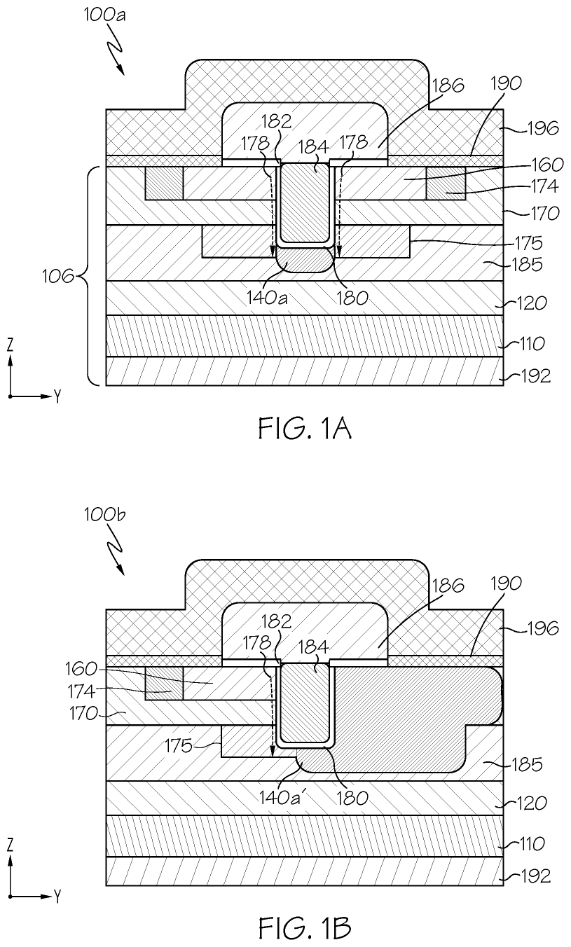

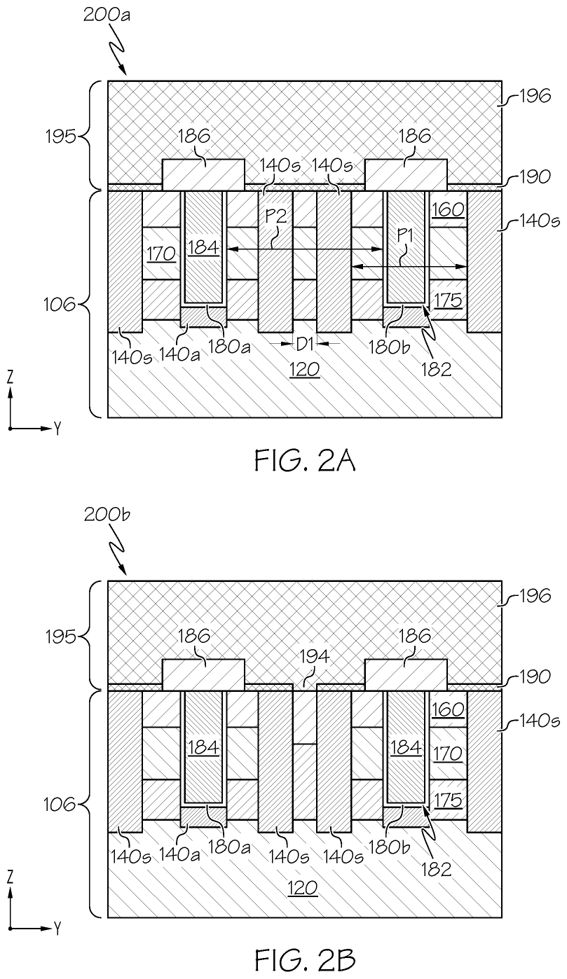

Various approaches may be used to form trenched vertical power semiconductor devices. FIGS. 1A and 1B schematically illustrate two examples of such different approaches.

FIGS. 1A and 1B are schematic cross-sectional views illustrating example transistor unit cells of trenched vertical power devices (illustrated as power MOSFET 100a and 100b, respectively) including bottom P-type shielding patterns 140a (also referred to herein as bottom shielding structures). As shown in FIGS. 1A and 1B, the power MOSFET 100a, 100b each include a heavily-doped (e.g., N⁺) first conductivity type (e.g., n-type) substrate 110. A lightly-doped (e.g., N⁻) first conductivity type drift layer or region 120 is provided on the substrate 110, for example by epitaxial growth. The drift region 120 may be wide bandgap semiconductor material (such as silicon carbide (SiC)) in some embodiments. For example, the substrate 110 may be a 4H-SiC substrate, and the drift region 120 may be a 4H-SiC n-type epitaxial layer formed on the substrate 110. A portion of the drift region 120 may include a current spreading layer (“CSL”) 185 of the first conductivity type having a higher dopant concentration than the lower portions of the drift region 120. A moderately-doped second conductivity type (e.g., p-type) layer is formed on or in (for example, by epitaxial growth or implantation) the drift region 120 and acts as the well regions (e.g., “P-wells”) 170 for the device 100a, 100b. Heavily-doped second conductivity type (e.g., P⁺) regions 174 are formed in the well regions 170, for example, via ion implantation. The transistor channels or conduction paths 178 may be formed in the moderately-doped regions P-wells 170. The substrate 110, drift region 120 (including current spreading layer 185), and the moderately doped layer defining the P-wells 170, along with the various regions/patterns formed therein, are included in a semiconductor structure (denoted by 106 herein).

Still referring to FIGS. 1A and 1B, trenches 180 are formed in the semiconductor structure 106, e.g., with “striped” gate trench layouts in which the trenches 180 continuously extend in parallel to one another in a first lateral direction. The trenches 180 are spaced apart in a second lateral direction crossing (e.g., perpendicular to) the first lateral direction, and extend into the drift region 120 toward the substrate 110 in a vertical direction. Lateral directions (e.g., the X-, Y-, or other directions in the X-Y plane) as described herein may be substantially perpendicular to vertical directions (e.g., the Z-direction) as described herein. The trenches 180 (in which the gates electrodes 184 are formed) may be formed to extend through the moderately-doped layer 170 to define the respective P-wells. Heavily-doped (e.g., P⁺) second conductivity type bottom shielding structures 140a, 140a′ are formed in the drift region 120, for example, by ion implantation. The bottom shielding structures 140a, 140a′ may be in electrical connection with the P-wells 170. A gate insulating layer 182 (e.g., a gate oxide) is conformally formed on the bottom surface and sidewalls of each trench 180. The corners of the gate trench 180 and the gate insulating layer 182 thereon may be rounded even if illustrated otherwise.

A gate electrode 184 (or “gate”) is formed on each gate insulating layer 182 to fill the respective gate trenches 180. Portions of the drift region 120 that are under the well regions 170 and/or adjacent a bottom of the gate electrode 184 may be referred to as “JFET” regions 175. Vertical transistor channel regions (with conduction 178 shown by dotted arrows) are defined in the well regions 170 adjacent the gate insulating layer 182 and controlled by the gate 184. Heavily-doped source regions 160 of the first conductivity type (e.g. N⁺) are formed in upper portions of the P-wells 170, for example, via ion implantation. The heavily-doped regions 174 of the second conductivity type (e.g., a P⁺) contact the well regions 170. Source contacts 190 are formed on the source regions 160, on the heavily-doped regions 174, and (in FIG. 1B) on the deep shielding structures 140a′. The source contacts 190 may be ohmic metal in some embodiments. A drain contact 192 is formed on the lower surface of the substrate 110. A gate contact (not shown) may be electrically connected to each gate electrode 184, for example, by a conductive gate bus (not shown). An intermetal dielectric layer 186 may be formed on the gates 184, and a metal (e.g., aluminum) layer 196 may be formed on the intermetal dielectric layer 186 to contact the source contacts 190. The source contacts 190 may extend on to the intermetal dielectric 186 layer in some embodiments, and may comprise, for example, diffusion barrier and/or adhesion layers.

As noted above, some devices may be susceptible to gate insulating layer degradation due to the electric field crowding effect near the corners of the gate trenches 180. In the examples of FIGS. 1A and 1B, bottom shielding patterns 140a, 140a′ of an opposite conductivity type than the drift region 120 are configured to prevent degradation of the trench MOSFET 100a, 100b at high electric fields. In particular, in the example devices 100a and 100b, the bottom shielding patterns 140a, 140a′ are configured to provide voltage and/or current blocking by connections to respective source contacts 190, which may be connected to ground. Shielding connection patterns may be connected to the source contacts 190 at the top of the device 100a, 100b (or may be otherwise connected to the bottom shielding patterns 140a, 140a′) to allow the bottom shielding patterns 140a, 140a′ to be electrically grounded.

The bottom shielding patterns 140a, 140a′ extend to one lower corner region (in FIG. 1B) or both lower corner regions (in FIG. 1A) at the bottom surfaces of the gate trenches 180. As the gate insulating layer 182 may be particularly susceptible to breakdown at the corner regions, the shielding patterns 140a may help protect the gate insulating layer 182 at the lower corner region(s) of the gate trenches 180 from high electric fields during reverse blocking operation.

FIG. 1A illustrates a bottom-gated shielding (BPS_TMOS) configuration of the shielding pattern 140a that may allow for aggressive unit cell pitch reduction and increased sidewall conductivity utilization. In particular, in FIG. 1A, conduction 178 (shown by dotted arrows) occurs along both sides of the channel in the device 100a. For more reliable on- and off-state performance and/or improved ruggedness, FIG. 1B illustrates a contacting scheme having an asymmetric shielding (APS_TMOS) configuration, where the shielding pattern 140a′ extends along only one sidewall of the trench 180, such that the other sidewall of the trench 180 is free of the shielding pattern 140a′. However, this configuration may limit the active conducting area of the device 100b by blocking conduction 178 at one side of the channel.

Embodiments of the present invention are directed to power semiconductor devices including layouts and design arrangements that further improve reliability by forming multiple support shielding structures or regions 140s between and spaced apart from sidewalls of immediately adjacent gate trenches 180, or vice versa. As used herein, “immediately adjacent” elements may refer to an arrangement of the recited elements in which no intervening elements of the same type as the recited elements are present between the recited elements (although other elements of a different type than the recited elements may be present). That is, immediately adjacent elements may refer to consecutive elements of an arrangement.

As noted above, support shielding structures 140s may be used in trench MOSFETs to shield the gate oxide and collect avalanche and displacement current during static and switching conditions of a power MOSFET. The support shielding structures 140s are of a second or opposite conductivity type (e.g., p-type) than the first conductivity type (e.g., n-type) of the drift region 120. Although described and illustrated herein with reference to regions of specific first and second conductivity types (i.e., n-type and p-type) by way of example, it will be understood that the conductivity types of the regions in any of the illustrated examples may be reversed (i.e., p-type and n-type) in accordance with embodiments of the present invention. Likewise, while described herein primarily with reference to MOSFET implementations, it will be appreciated that the same techniques may be used in other vertical power semiconductor devices, such as insulated gate bipolar transistors (IGBTs), and/or other related power devices utilizing a trenched structure.

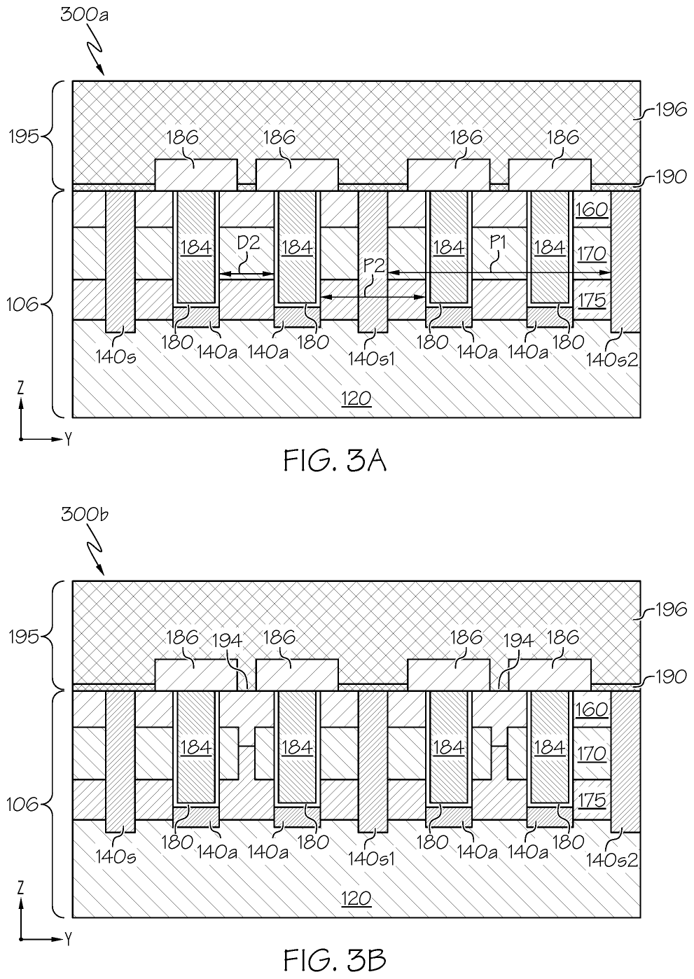

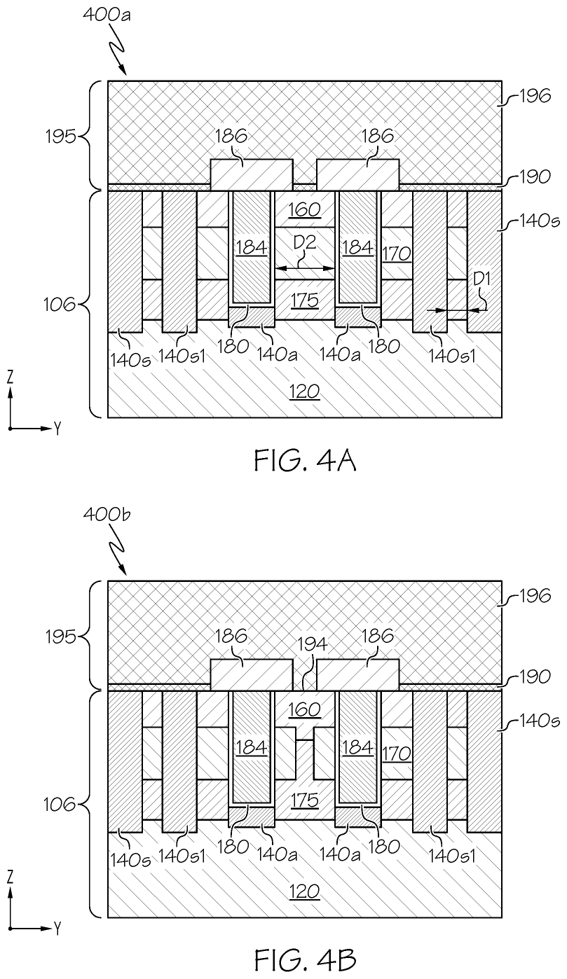

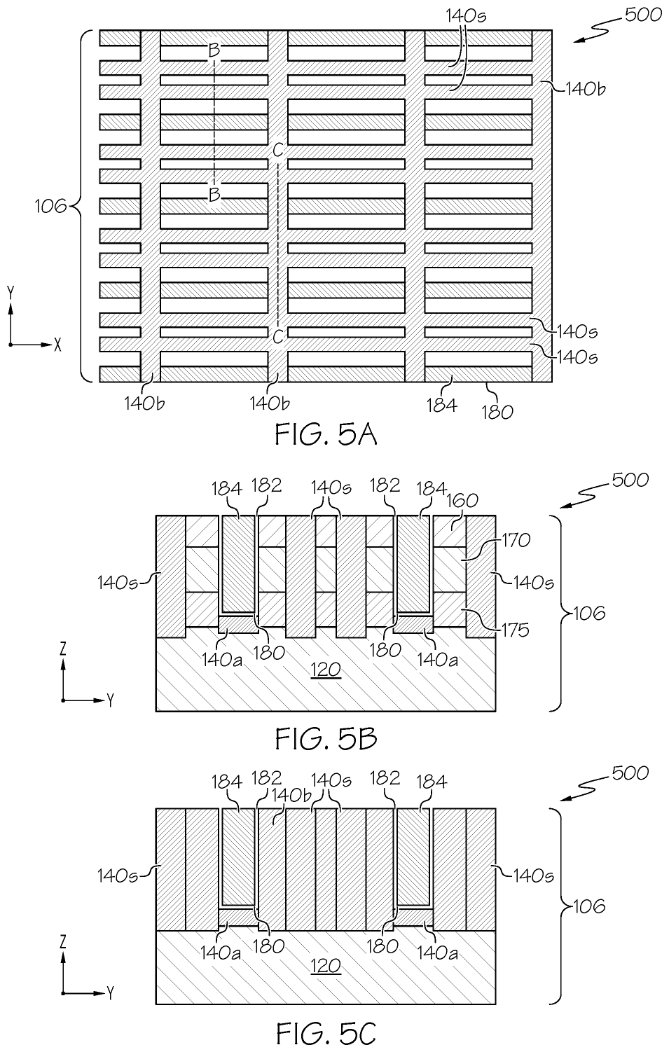

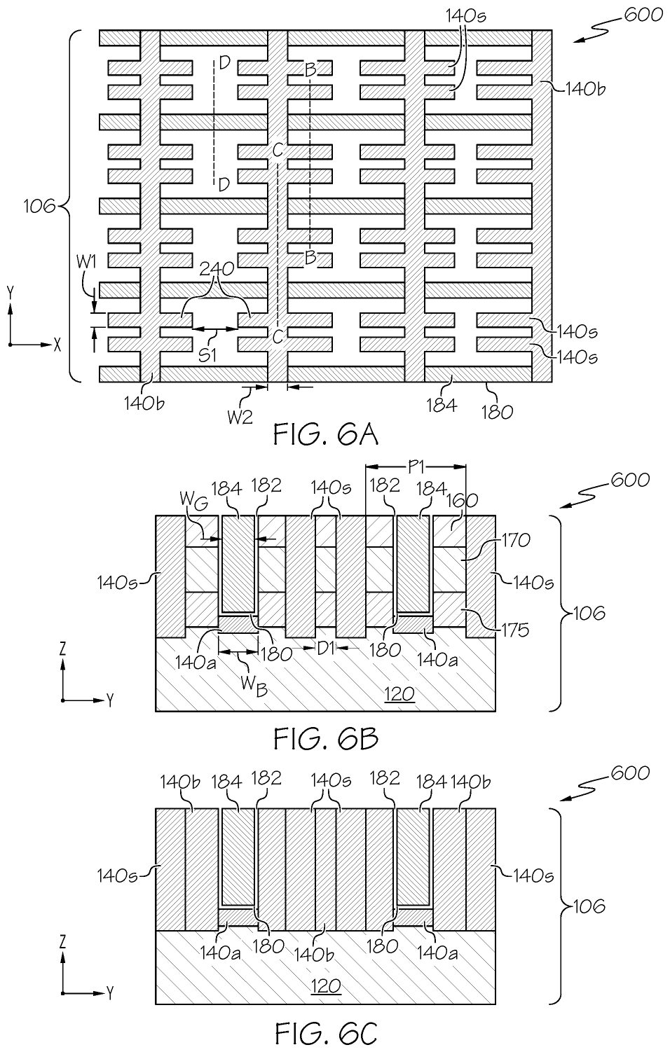

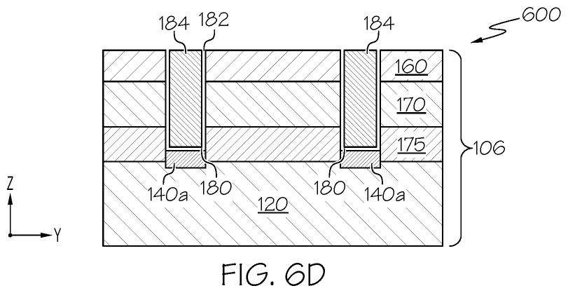

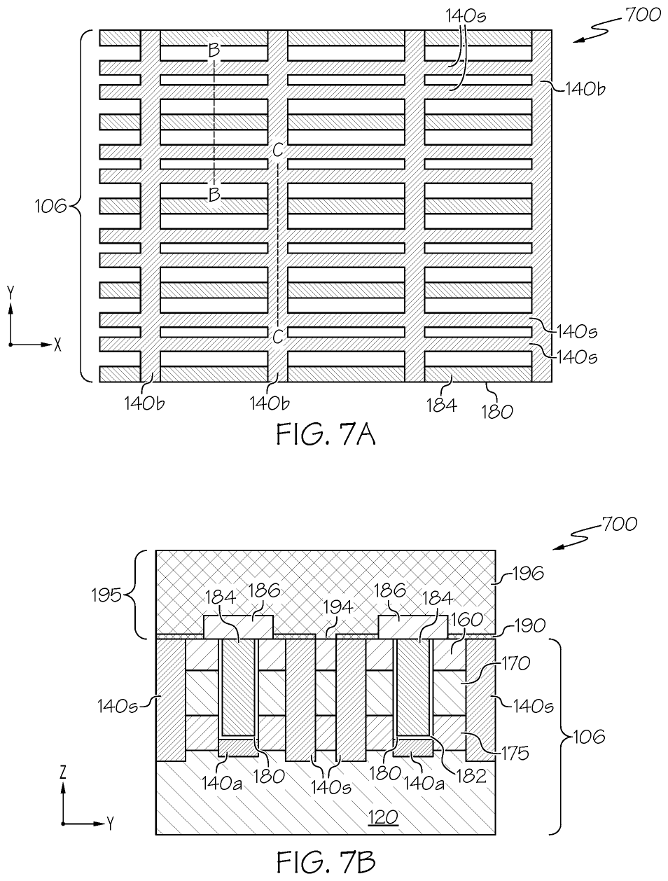

FIG. 2A is a schematic cross-sectional view illustrating example unit cells of a gate trench power semiconductor device including multiple shielding (or “split shielding”) structures between immediately adjacent gate trenches according to some embodiments of the present disclosure. FIG. 3A is a schematic cross-sectional view illustrating example unit cells of a gate trench power semiconductor device including multiple gate (or “split gate”) structures according to some embodiments of the present disclosure. FIG. 4A is a schematic cross-sectional view illustrating example unit cells of a gate trench power semiconductor device including split support shielding structures and split gate structures according to some embodiments of the present disclosure. Trenched vertical power semiconductor devices including multiple support shielding structures 140s can provide improved switching characteristics. In particular, rather than implementing the support shielding structures as a single continuous pattern or stripe between gates 184/trenches 180, providing multiple support shielding structures 140s between immediately adjacent pairs of gates 184/gate trenches 180 may improve collection of avalanche current, displacement current density, and/or body diode conduction, while maintaining a same or desired cell pitch for the unit cells as some single stripe support shielding structure configurations.

FIG. 2B is a schematic cross-sectional view illustrating example unit cells of a gate trench power semiconductor device including split support shielding structures and integrated Schottky diodes according to some embodiments of the present disclosure. FIG. 3B is a schematic cross-sectional view illustrating example unit cells of a gate trench power semiconductor device including split gate structures and integrated Schottky diodes according to some embodiments of the present disclosure. FIG. 4B is a schematic cross-sectional view illustrating example unit cells of a gate trench power semiconductor device including split support shielding structures, split gate structures, and integrated Schottky diodes according to some embodiments of the present disclosure. That is, FIGS. 2B, 3B, and 4B illustrate trenched vertical power semiconductor devices 200b, 300b, 400b including a metal contact 195 that forms a Schottky barrier with the semiconductor structure 106 between gates 184 and/or between support shield structures 140s. Further illustration and/or description of elements or structures that are similar to those discussed above with reference to FIGS. 1A and 1B may be omitted for brevity.

As shown in FIGS. 2A to 4B, trenched vertical power semiconductor devices 200a/200b, 300a/300b, 400a/400b include a semiconductor structure 106 having a drift region 120 of a first conductivity type (e.g., N-type). A plurality of gate trenches 180 respectively including sidewalls and a bottom surface therebetween extend in parallel to one another in a first direction (e.g., the X-direction) in the semiconductor structure 106. The trenches 180 are spaced apart in a second direction (e.g., the Y-direction) with portions of the semiconductor structure 106 therebetween, extend into the drift region 120 in a vertical direction (e.g., the Z-direction), and extend through a moderately-doped layer of a second conductivity type (e.g., P-type) to define respective well regions 170. A plurality of heavily-doped (e.g., P⁺) support shielding structures 140s of the second conductivity type are formed in the drift region 120, for example, by ion implantation or deposition. The support shielding structures 140s may be in electrical connection with the well regions 170, and may extend in the first direction (e.g., the X-direction) in the semiconductor structure 106, parallel to the gate trenches 180. The support shielding structures 140s are spaced apart from the sidewalls of the gate trenches 180 in the second direction (e.g., the Y-direction) with portions of the semiconductor structure 106 therebetween.

A gate insulating layer 182 (e.g., a gate oxide) is conformally formed on the bottom surface and sidewalls of each gate trench 180, and gate electrode 184 (or “gate”) is formed on each gate insulating layer 182 to fill the respective gate trenches 180. Upper portions of the drift region 120 that are under the well regions 170 and/or adjacent a bottom of the gate electrodes 184 may be referred to as JFET regions 175. A plurality of bottom shielding structures 140a of the second conductivity type extend in the semiconductor structure 106 in the first direction (e.g., the X-direction) under the gate trenches 180, respectively. As one or more support shielding structures 140s are provided on opposing sides of and spaced apart from the sidewalls of the gate trenches 180, the JFET regions 175 extend at least partially between each support shielding structure 140s and the bottom shielding structures 140a.

The bottom and support shielding structures 140a and 140s (which may collectively be referred to as shielding structures) extend towards the substrate 110 beyond the gate trenches 180 (i.e., extend closer to the substrate 110 than the gate trench 180). The source contacts 190 (e.g., at the top of the devices 200a/200b, 300a/300b, 400a/400b) may be electrically connected to the shielding structures 140a, 140s to allow the shielding structures 140a, 140s to be electrically grounded.

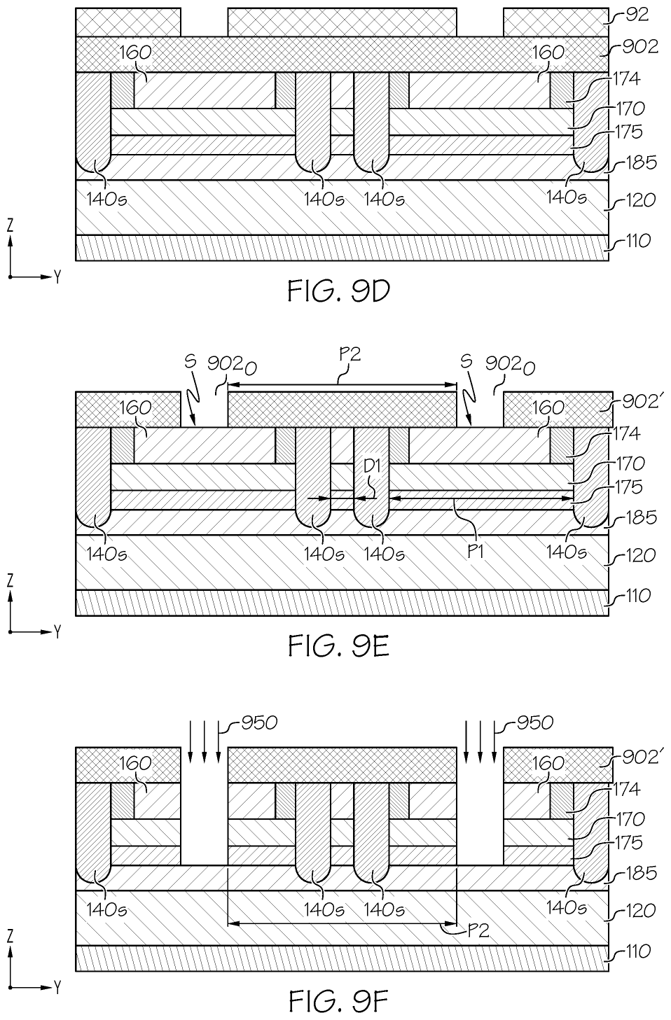

The support shielding structures 140s may differ from the bottom shielding structures 140a (e.g., in material composition, depth of extension toward the substrate 110, and/or dopant concentration) so as to provide greater protection for the gate insulating layer 182 along the gate trenches 180 (e.g., at corners of the bottom surface of the gate trenches 180) by providing a lower resistance current path under avalanche breakdown conditions. In some embodiments, the support shielding structures 140s may extend towards the substrate 110 to a depth that is substantially equal to the depth of the bottom shielding structures 140a. In some embodiments, the support shielding structures 140s may extend towards the substrate 110 to a greater depth than the depth of bottom shielding structures 140a. For example, the support shielding structures 140s may extend toward the substrate 110 beyond the bottom shielding structures 140a by a depth ΔD of about 0.1 microns to about 1 micron (e.g., about 0.3 microns to about 0.7 microns, for example, about 0.5 microns). That is, a difference ΔD between the depth of the support shielding structures 140s and the depth of the bottom shielding structures may be less than about 0.1 microns to about 1 micron. Depths or depths of extension into the drift region 120 as described herein may be along the vertical direction (e.g., the Z-direction) in the drawings, and may be relative to a top surface (e.g., surface S shown in FIGS. 9A-9F) of the semiconductor structure 106. The depth of the support shielding structures 140s may be sufficient to reduce or prevent avalanche breakdown at the bottom of the gate trench 180. In some embodiments, the support shielding structures 140s may extend from the surface S of the semiconductor structure 106 to a depth that is about 1 micron to about 10 microns (e.g., about 3 microns to about 7 microns, for example, about 5 microns) towards the substrate 110.

The shapes of the support shielding structures 140s may differ from the bottom shielding structures 140a and/or from the trenches 180 in some embodiments. For example, the widths of the support shielding structures 140s (along the horizontal or Y-direction) may differ from the width of the trenches 180 (and/or bottom shielding structures 140a extending under the trenches 180). That is, while illustrated as substantially similar in width, the support shielding structures 140s may be wider than, narrower than, or substantially equal in width to the gate trenches 180 in some embodiments.

The support shielding structures 140s may define a p-n junction (e.g., a body diode) with the drift region 120. A vertical separation between the support shielding structures 140s and the substrate 110 (e.g., defined by a portion of the drift region 120 therebetween in the Z-direction) may correspond to a breakdown voltage of the device 200. For example, the support shielding structures 140s and/or the bottom shielding structures 140a may be separated from the substrate 110 by about 1 micron to about 100 microns (e.g., about 30 microns to about 70 microns, for example, about 50 microns). The separation may vary, for example, based on the materials and/or dopant concentrations of the shielding structures 140a, 140s.

In some embodiments, the support shielding structures 140s may have a lower resistance than the bottom shielding structure 140a. For example, the support shielding structures 140s may contact the source contact 190 over a greater length (e.g., along a direction into the page) than the bottom shielding structure 140a (which may only connect to the source intermittently along its length), thereby reducing resistance. The support shielding structures 140s may be formed of a same or different material and/or with a similar or different dopant concentration than the bottom shielding structures 140a. In some embodiments, the shielding structures 140a, 140s may be defined by one or more implantation processes, with substantially uniform concentration or stepwise or continuous grading, and may extend to contact the source contact 190 for connection to electrical ground within the unit cell. The support shielding structures 140s may include a concentration of dopants of the second conductivity type of about 1×10¹⁷ to about 1×10²⁰ cm⁻³, e.g., about 5×10¹⁷ to about 5×10¹⁹ cm⁻³, or about 1×10¹⁸ to about 1×10¹⁹ cm⁻³. The dopant concentration of the support shielding structures 140s may be higher than that of the well regions 170 (e.g., more than about 10 times higher; for example, about 100 times higher), and may be similar to or higher than the dopant concentration of the bottom shielding structures 140a. The dopant concentrations of the shielding structures 140a, 140s may vary based on implementation of the fabrication process and/or device design.

In some embodiments, the shielding structures 140a, 140s may be formed of different materials than the drift region 120, e.g., a semiconductor material with lower resistance than the semiconductor material of the drift region 120. For example, in embodiments where the drift region 120 is an n-type material (e.g., SiC), the support shielding structures 140s and/or the bottom shielding structures 140a may be p-type material(s) (e.g., nickel oxide (p-NiO), polysilicon (poly-Si), gallium nitride (p-GaN), gallium oxide (p-Ga₂O₃)). In embodiments where the drift region 120 is a p-type material, the support shielding structures 140s and/or the bottom shielding structures 140a may be n-type material(s) (e.g., n-SiC, n-Si, n-GaN). Forming the shielding structures 140a and/or 140s of different material(s) of the opposite conductivity type than the drift region 120 may thus define respective p-n heterojunctions or body diodes in the drift region 120.

Shielding structures 140a, 140s formed of different material(s) that define heterojunctions with the drift region 120 may also differ in ability to withstand repeated breakdown events (in comparison to implanted shielding structures). For example, heterojunction-based shielding structures 140a, 140s may be formed to provide a lower resistance and/or to extend to greater depths than the implant-based shielding structures 140a, 140s to increase effectiveness. That is, relative to implant-based shielding regions, heterojunction-based shielding structures may provide advantages with respect to resistance and/or depth control (i.e., can be formed with lower resistance and/or greater depth than implanted shielding structures).

In addition or alternatively, the support shielding structures 140s may be formed of different materials than the bottom shielding structures 140a. For example, the bottom shielding structures 140a may be implanted regions of (and thus, may be of the same material as) the drift region 120, while the support shielding structures 140s may be deposited in trenches in (and thus, may be formed of a different material than) the drift region 120, or vice versa. As such, in some embodiments, the shielding structures 140a, 140s may be a same material as the drift region 120, while in other embodiments, the material composition of the shielding structures 140a, 140s may be different from that of the drift region 120. For example, the drift region 120 may be a wide bandgap semiconductor material, and the bottom shielding structures 140a or the support shielding structures 140s may include polysilicon, nickel oxide, gallium nitride, or gallium oxide. Forming the shielding structures 140a and/or 140s of different materials than one another may provide improved protection of the gate insulating layer 182. For example, forming the support shielding structures 140s of different materials of the second conductivity type (e.g., p-NiO, p-poly-Si, p-GaN, p-Ga₂O₃) may provide a lower resistance (in some instances, a few orders of magnitude lower) than some implanted bottom shielding structures 140a of the second conductivity type (e.g., P⁺ regions), and thus, a lower resistance current path under avalanche breakdown conditions. That is, the shielding structures 140a, 140s may be formed of different materials than the drift region 120, and/or may be formed of different materials than one another.

The shape and/or depths of the support shielding structures 140s may also allow for variations in shape and/or depth of the bottom shielding structures 140a while still providing desired avalanche breakdown characteristics. For example, in some embodiments, due to the greater protection of the gate oxide 182 provided by the support shielding structures 140s, the bottom shielding structure 140a may extend along only a portion of (i.e., may be narrower than) the bottom surface of the gate trench 180, which may increase the available area for conduction 178 at the bottom corners of the gate trench 180 (such that the JFET region 175 may extend underneath the outer edges of the gate trench 180, in addition to along the trench sidewalls). In contrast, in some embodiments, the bottom shielding structure 140a may extend along an entirety of (or may extend laterally beyond or wider than) the bottom surface of the gate trench 180, and a dopant concentration of the JFET region 175 may be increased to maintain the desired conduction 178. The width of the bottom shielding structure 140a (i.e., along the bottom of the gate trench 180) may be varied based on the masking, implantation, deposition, and/or other fabrication operations that are used to form the shielding structures 140a and 140s.

More generally, the support shielding structures 140s may be formed with a different depth, dopant concentration, and/or material than the bottom shielding structures 140a, one or more of which may be configured to reduce or prevent avalanche breakdown at the bottom of the gate trenches 180.

Still referring to FIGS. 2A to 4B, at least two of the support shielding structures 140s are between immediately adjacent pairs 180a,180b of the gate trenches 180 (or gates 184), as shown in FIGS. 2A-2B and 4A-4B, or at least two of the gate trenches 180/gates 184 are between immediately adjacent pairs 140s1, 140s2 of the support shielding structures 140s (as shown in FIGS. 3A-3B and 4A-4B). That is, a subset of the support shielding structures 140s may include first and second support shielding structures 140s that are free of gate trenches 180/gates 184 therebetween, or a subset of the gate trenches 180/gates 184 may include first and second gates gate trenches 180/gates 184 that are free of support shielding structures 140s therebetween. In the embodiments of FIGS. 2A-2B and 4A-4B, the support shielding structures 140s that are free of gate trenches 180/gates 184 therebetween are spaced apart by a first distance D1 that is less than a distance (or pitch P1) between pairs of the support shielding structures 140s having one or more of the gate trenches 180/gates 184 therebetween. In the embodiments of FIGS. 3A-3B and 4A-4B, the gate trenches 180/gates 184 that are free of support shielding structures 140s therebetween are spaced apart by a second distance D2 that is less than a distance (or pitch P2) between pairs of the gate trenches 180/gates 184 having one or more of the support shielding structures 140s therebetween. As noted above, implementing multiple support shielding structures 140s between immediately adjacent pairs of gate trenches 180 (or vice versa) may provide improved avalanche performance, displacement current density, and/or body diode conduction.

The support shielding structures 140s and the gate trenches 180 may thus be formed to extend in parallel in the same direction (e.g., in the X-direction) but with different repeating patterns or pitches (e.g., in the Y-direction). As such, immediately adjacent pairs of the support shielding structures 140s having one or more of the gate trenches 180 therebetween may be spaced apart in the semiconductor structure 106 at a first spacing or pitch P1, while immediately adjacent pairs of the gate trenches 180 having one or more of the support shielding structures 140s therebetween may be spaced apart in the semiconductor structure 106 at a second spacing or pitch P2 that is different from the first spacing or pitch P1.

Furthermore, as shown in the embodiments of FIGS. 2B, 3B, and 4B, a metal contact 195 provides a Schottky barrier 194 with a portion of the semiconductor structure 106 between the gate trenches 180, thereby providing an integrated Schottky diode. The semiconductor structure 106 further includes a p-n junction (e.g., between vertically-extending portions of the source region 160 and the JFET region 175) under the Schottky barrier 194 between the gate trenches 180. In FIG. 2B, the p-n junctions are provided between two or more of the support shielding structures 140s that are arranged between immediately adjacent pairs 180a, 180b of gate trenches 180/gates 184. In FIGS. 3B and 4B, the p-n junctions are provided between two or more of the gate trenches 180/gates 184 that are arranged between immediately adjacent pairs 140s1, 140s2 of support shielding structures 140s. The metal contact 195 and the portion of the semiconductor structure 106 between the gate trenches 180 may provide a bipolar pin diode in the off-state (when no current is applied to the metal contact 195), or as a unipolar Schottky diode in the on-state (when current is applied to the metal contact 195).

As shown in FIGS. 2B, 3B, and 4B, the metal contact 195 includes a first metal layer 190 that provides the source contacts, and also provides ohmic contacts with the support shielding structures 140s. The metal contact 195 further includes a second metal layer 196 that provides the Schottky barrier 194 with the semiconductor structure 106. However, it will be understood that the metal contact 195 may include fewer or more metal layers than those specifically shown. For example, in some embodiments the metal contact 195 may be a single or continuous layer, and may include respective portions that locally provide the Schottky barrier 194 with the semiconductor structure 106 and ohmic contacts with the support shielding structures 140s.

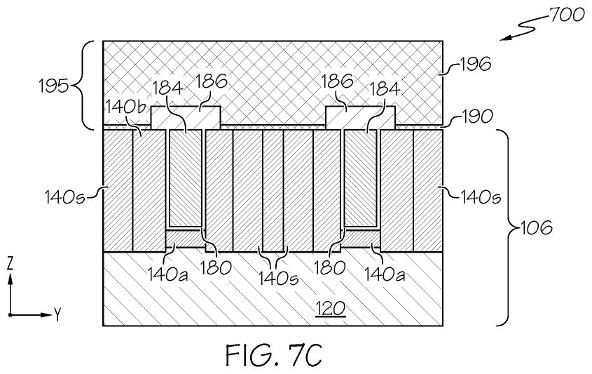

Example unit cells of power semiconductor devices including various combinations of support shielding structures 140s are illustrated in FIGS. 5A-8D. While the power semiconductor devices 500, 600, 700, and 800 of FIGS. 5A-8D further illustrate variations in the configurations 200a and 200b shown in FIGS. 2A and 2B, it will be understood embodiments of the present disclosure are not so limited, and that similar variations may be implemented in the configurations 300a, 300b, 400a, and 400b shown in FIGS. 3A-4B. Likewise, in the examples of FIGS. 5A-8D, a simplified semiconductor structure 106 (e.g., without the JFET regions 175, CSL 185, metal contacts 195, etc.) is shown for ease of illustration, but these and other well-known elements may be understood to be present although not specifically shown. Elements, layers, and/or regions of the devices 200a and 200b similar to those discussed above are indicated by like numbers, and description of such elements, layers, and/or regions may be omitted for brevity.

Referring now to the plan views of FIGS. 5A, 6A, 7A, and 8A, the power semiconductor devices 500, 600, 700, and 800 include gate trenches 180 having gate electrodes 184 therein longitudinally extending in a first lateral direction (e.g., the X-direction) in the semiconductor structure 106, and support shielding structures 140s of a second conductivity type longitudinally extending in the first lateral direction in the semiconductor structure 106 parallel to and spaced apart from the gates 184, with portions of the semiconductor structure 106 therebetween. Multiple (shown as two) of the support shielding structures 140s are between immediately adjacent pairs of the gate trenches 180/gates 184, and are spaced apart from the sidewalls of the gate trenches 180 in a second lateral direction (e.g., the Y-direction) that crosses the first direction. Bottom shielding structures 140a of the second conductivity type extend in the semiconductor structure 106 in the first direction under the gate trenches 180. While illustrated as linearly extending in the first lateral direction by way of example, it will be understood that the bottom shielding structures 140a, the support shielding structures 140s, and/or the gate trenches 180/gates 184 may extend in other shapes, including (but not limited to) linear, elliptical, or polygonal shapes in plan view.

Still referring to the plan views of FIGS. 5A, 6A, 7A, and 8A, bridge shielding structures 140b of the second conductivity type longitudinally extend in the semiconductor structure 106 in the second lateral (e.g., Y−) direction, which intersects the direction of extension of the gate trenches 180 to contact the bottom shielding structures 140a under the gates 184. The bridge shielding structures 140b may electrically connect the bottom shielding structures 140a to the support shielding structures 140s, which (as noted above) may be electrically connected to a ground or reference voltage by the source contacts 190 at the top of the devices 500, 600, 700, 800. The support shielding structures 140s and the bridge shielding structures 140b have respective widths W1 and W2 (along a direction crossing their respective longitudinal directions of extension) and/or respective depths (along a vertical (e.g., Z−) direction from the top of the devices 500, 600, 700, 800 towards the drift region 120 or underlying substrate 110). For example, the respective widths W1 and W2 may be between about 0.1 and about 20 microns, or about 0.1 to about 10 microns. In some embodiments, the respective width and/or depths of the bridge shielding structures 140b and the support shielding structures 140s may be substantially equal, which may ease manufacturability and/or one or more fabrication operations as further described herein. The support shielding structures 140s may extend into the drift region 120 to their respective depths beyond the bottom shielding structures 140a.

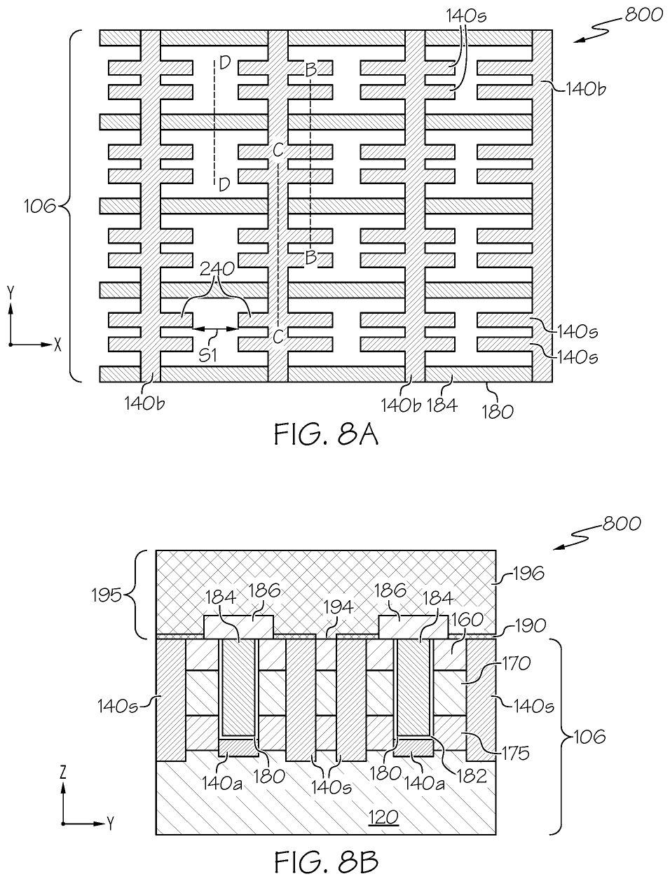

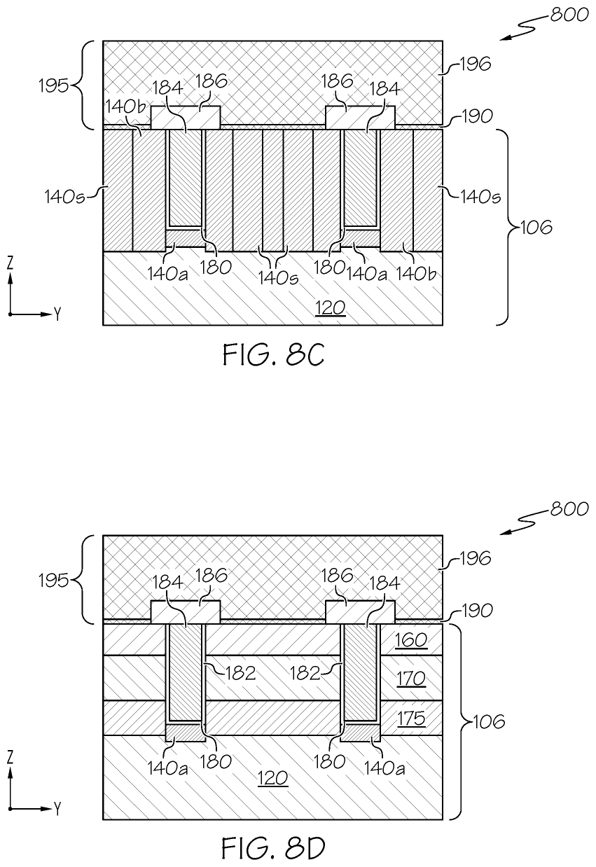

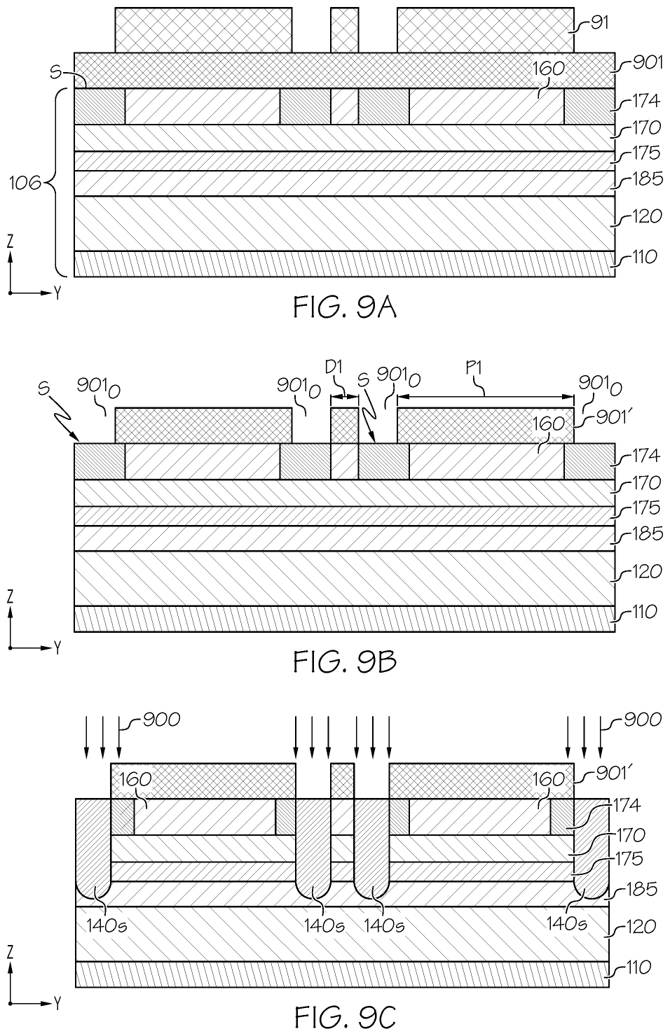

In some embodiments, as shown in FIGS. 5A and 7A, the support shielding structures 140s and the bridge shielding structures 140b continuously extend in the first and second directions, respectively. In other embodiments, as shown in FIGS. 6A and 8A, the support shielding structures 140s and/or the bridge shielding structures 140b may be discontinuous or segmented (with respective spacings S between segments 240) so as to reduce or minimize obstruction of the active conduction area of the semiconductor structure 106, thereby providing additional area in the semiconductor structure 106 for current flow.

In particular, the support shielding structures 140s (and/or the bridge shielding structures 140b) may include a plurality of discrete segments 240 that extend longitudinally (e.g., lengthwise) in one or more lateral directions (e.g., in the X-direction, the Y-direction, or other directions in the X-Y plane), and may have respective segments widths along a direction crossing the respective longitudinal directions of extension. For example, as shown in FIGS. 6A and 8A, the support shielding structures 140s include segments 240 with spacings S1 therebetween along the X-direction, while the bridge shielding structures 140b continuously extend along the Y-direction. The spacings S1 between segments 240 of the support shielding structures 140s are aligned along the Y-direction in the example devices 600, 800, but it will be understood that the spacings S1 between segments 240 may be misaligned or staggered along the Y-direction in some embodiments. Additionally or alternatively, spacings (not shown) may be similarly provided between the segments of the bridge shielding structures 140b along the Y-direction.

The respective spacings S1 between segments 240 (e.g., along the respective longitudinal directions of extension of the segments 240) may be sufficient to avoid punch-through (e.g., at the well regions) or otherwise avoid premature breakdown of the devices. As such, segmented shielding structures as described herein may provide similar blocking capabilities as compared to continuously extending shielding structures, while reducing on-resistance (Rds, on) for a given area of a device. The spacings between the segments 240 can differ in various embodiments so as to improve or optimize performance. For example, providing more segments 240 of the shielding structures 140s/140b may improve avalanche capabilities (by providing the shielding patterns with greater peripheral area to distribute avalanche current), but increasing the number of shielding structures 140s/140b may increase device on-resistance (due to reduction of the available active area in the semiconductor structure).

More generally, the plan views of FIGS. 5A, 6A, 7A, and 8A discussed above are provided by way of example only, and it will be understood that embodiments of the present disclosure are in no way limited to the arrangements or patterns shown in the examples described herein. For example, embodiments of the present disclosure may include support shielding structures 140s and/or bridge shielding structures 140b that are discontinuous or segmented in one or more lateral directions, as well as combinations thereof, with linear, elliptical, or polygonal shapes in plan view.

FIGS. 5B-5C, 6B-6D, 7B-7C, and 8B-8D illustrate various cross-sections of the semiconductor devices 500, 600, 700, and 800, respectively. As shown in these cross-sectional views, the semiconductor structure 106 includes a drift region 120 of a first conductivity type and a well region 170 of a second conductivity type in or above the drift region. The drift region 120 may also include an (optional) current spreading layer of the first conductivity type below the well region 170 in some embodiments. A gate trench 180 having opposing sidewalls and a bottom surface therebetween vertically extends through the well regions and into the drift region 120, with a gate insulating layer 182 and gate 184 extending between sidewalls of the gate trench 180. A portion 175 of the drift region under the well region 170 and the bottom of the gate trench 180 may be referred to as the JFET region 175. Support shielding structures 140s and bridge shielding structures 140b vertically extend from the well region 170 into the drift region 120.

In particular, FIGS. 5B, 6B, 7B, and 8B illustrate cross-sections of example support shielding structures 140s. The support shielding structures 140s longitudinally extend in a first lateral direction (shown as the X-direction) and are spaced apart from respective gates 184/trenches 180 in a second lateral direction (shown as the Y-direction). In the cross-sections shown in FIGS. 5B, 6B, 7B, and 8B, multiple (i.e., two or more) support shielding structures 140s are provided between and spaced apart from opposing sidewalls of immediately adjacent gate trenches 180. As noted above, the support shielding structures 140s may be configured to reduce electric field concentration in the gate insulating layers 182 during device operation. The support shielding structures 140s may also provide a low-resistance current path between the source (e.g., 190) and drain (e.g., 192) terminals of the devices 500, 600, 700, and 800 in case of avalanche breakdown.

In the cross-sections shown in FIGS. 6D and 8D, the support shielding structures 140s are segmented such that no support shielding structures 140s are adjacent the opposing sidewalls of the gate trenches 180, so as to provide the above advantages with respect to electric field concentration and avalanche performance while also increasing or maximizing the area of the semiconductor structure 106 that is available for conduction. In particular, the segments 240 of the support shielding structures 140s (and/or the bridge shielding structures 140b) are laterally spaced apart to define a relatively sparse pattern such that the shielding structures 140b, 140s are absent in portions of the semiconductor structure 106. That is, the respective spacings between the discrete segments 240 may include portions of the drift region 120 between the well region 170 and the drain contact (not shown) that are free of the shielding structures 140b, 140s, thereby providing devices 600, 800 with additional conduction area in comparison to the devices 500, 700 having continuously extending shielding structures 140b, 140s. In some embodiments, the spacings between segments 240 may be provided such that fewer than one bridge shielding structure 140b is included in each transistor unit cell, thereby further increasing the available conduction area in the semiconductor structure 106.

FIGS. 5C, 6C, 7C, and 8C illustrate cross-sections of the bridge shielding structures 140b. The bridge shielding structures 140b longitudinally extend towards the gates 184 in a lateral direction (shown as the Y-direction) that crosses the direction of extension of the support shielding structures 140s (shown as the X-direction). As noted above, the bridge shielding structures 140b may be configured to electrically connect the support shielding structures 140s to bottom shielding structures 140a that extend (continuously or discontinuously) under the bottom surfaces of the gate trenches 180 to reduce or prevent electric field breakdown of the gate insulating layer 182, particularly at corners of the gate trenches 180. The bridge shielding structure 140b may extend on one sidewall (when segmented) or both sidewalls of a respective gate trench 180 (i.e., forming a one-sided or two-sided “bridge” that contacts the bottom shielding structure 140a). The cross-sections shown in FIGS. 5C, 6C, 7C, and 8C illustrate the two-sided bridge shielding structures 140b extending along both of the opposing sidewalls of the gate trenches 180 to contact the bottom shielding structures 140a. However, it will be understood that the bridge shielding structures 140b may discontinuously extend along the second direction to provide one-sided bridge shielding structures 140b, which are segmented so as to extend along only one of the sidewalls of the gate trench 180 to contact the bottom shielding structures 140a, thereby allowing conduction along the opposite sidewall of the gate trenches 180 (which is thus free of the bridge shielding structures 140b).

In either the one-sided or two-sided bridge configurations, the bridge shielding structures 140b electrically couple the bottom shielding structure 140a to heavily-doped regions (e.g., 174) and source contacts 190 on a surface of the semiconductor structure 106. In particular, a source region 160 of the first conductivity type and a heavily-doped region of the second conductivity type may be provided above the well region 170, and the source contact 190 may be electrically coupled to the source region 160 and the heavily-doped region at the surface of the semiconductor structure 106. An intermetal dielectric layer 186 separates the gate 184 from metal layer(s) 196 formed to contact the source contacts 190. The bridge shielding structures 140b (or segments 240 thereof) vertically extend from the source contact 190 to the bottom shielding structure 140a, and laterally extend from the bottom shielding structure 140a to contact the support shielding structures 140s (or segments 240 thereof), to provide electrical connection to the source contact 190, which is electrically coupled to the source region 160 at the top surface of the semiconductor structure 106 (e.g., opposite the drain contact 192 in FIG. 1A).

FIGS. 7A-7C and 8A-8D further illustrate integration of Schottky diodes into semiconductor structures 106 according to some embodiments of the present disclosure. In particular, FIGS. 7A-7C illustrate a power semiconductor device 700 including split support shielding structures 140s and integrated Schottky diodes (e.g., with a structure similar to that of the embodiments of FIGS. 5A-5C), while FIGS. 8A-8D illustrate a power semiconductor device 800 including segmented split support shielding structures 140s and integrated Schottky diodes (e.g., with a structure similar to that of the embodiments of FIGS. 6A-6D).

As shown in FIGS. 7A-7C and 8A-8D, the power semiconductor devices 700, 800 include gate trenches 180 and support shielding structures 140s extending in the first direction in the semiconductor structure and spaced apart from one another in the second direction. The semiconductor structure 106 may also include p-n junctions (e.g., between vertically-extending portions of the source region 160 and the JFET region 175) between two or more gates 184/gate trenches 180, as also shown in the power semiconductor devices 200b, 300b, and 400b of FIGS. 2B, 3B, and 4B. In the power semiconductor devices 700 and 800 of FIGS. 7A-7C and 8A-8D, the p-n junctions are also provided between two or more of the support shielding structures 140s that provide the split support shielding structures described herein.

As shown in FIGS. 7B and 8B, a metal contact 195 forms a metal-semiconductor junction (creating a Schottky barrier 194) with portions of the semiconductor structure 106 between two or more gates 184/gate trenches 180 above the p-n junctions, and in particular embodiments between two or more support shielding structures 140s of the split support shielding structures. The metal contact 195 and the portions of the semiconductor structure 106 between the gates 184/trenches 180 thus provide a Schottky diode that is integrated in the semiconductor structure 106.

In particular, the metal contact 195 and the portions of the semiconductor structure 106 between the gates 184/trenches 180 may function as a bipolar pin diode when no current is applied to the metal contact 195 (i.e., in the off-state), or as a unipolar Schottky diode when current is applied to the metal contact 195 (i.e., in the on-state). The Schottky diode may provide advantages with respect to increased switching speed with reduced losses and lower forward voltage drop in comparison to semiconductor-semiconductor junction-based diodes. While a higher electric field gradient may result at edges of the portions of the metal contact 195 forming the Schottky barrier 194 with the semiconductor structure 106, implementing the Schottky barrier 194 between support shielding structures 140s (as shown in the devices 700, 800) may effectively spread the electric field gradient.

The metal contact 195 may be implemented by one or more metal layers. For example, as shown in the examples of FIGS. 7B-7C and 8B-8D, the metal contact 195 may include a first metal layer 190 that provides ohmic contacts with the support shielding structures 140s and a second metal layer 196 that provides the Schottky barrier with the semiconductor structure 106. However, it will be understood that the metal contact 195 may instead be implemented by a single or continuous layer having respective portions that locally provide the Schottky barrier 194 with the semiconductor structure 106 and ohmic contacts with the first and second support shielding structures 140s.

FIGS. 9A, 9B, 9C, 9D, 9E, and 9F are schematic cross-sectional views illustrating various example fabrication operations for methods of forming power semiconductor devices including split support shielding structures and gate trenches according to some embodiments of the present disclosure. In particular, FIGS. 9A-9F illustrate methods of forming the split support shielding structures 140s prior to forming the gate trench 180 (i.e., using a pre-trench shield implant or deposition process), but it will be understood that the split support shielding structures 140s may be formed after formation of the gate trenches 180 (i.e., using a post-trench shield implant or deposition process). That is, fabrication methods as described herein are not limited to the order of fabrication operations specifically illustrated. Also, will be understood that selective epitaxy, ion implantation, etching, and/or combinations thereof may be used to form the split shielding structures 140s as described herein.

As shown in FIGS. 9A-9F, a drift region 120 having a first (e.g., n−) conductivity type is formed on a substrate 110, for example, by an epitaxy process. A JFET region 175 of the first conductivity type, a well region 170 of a second (e.g., p−) conductivity type, and a source region 160 of the first conductivity type are formed in or on the drift region 120. For example, the JFET region 175, the well region 170, and the source region 160 may be formed in the drift region 120 by respective masking and/or ion implantation processes. In some embodiments, additional shallow contact structures 174 of the second conductivity type (e.g., P+ regions) may be formed adjacent the source region 160 to provide electrical contact to the well region 170. A semiconductor structure 106 including the drift region 120, well region 170, and source region 160 is thereby provided.

As shown in FIG. 9A, a mask layer 901 is formed on the surface S of the semiconductor structure 106, and a patterning layer 91 is formed on the mask layer 901. In FIG. 9B, the mask layer 901 is patterned (e.g., photolithographically) using the patterning layer 91 to form a first mask pattern 901′. The first mask pattern 901′ includes respective first openings 901o therein exposing portions of the surface S of the semiconductor structure 106. Adjacent first openings 901o are spaced apart by a distance D1 or pitch P1 in a lateral (e.g., Y−) direction.

In FIG. 9C, one or more ion implantation processes 900 are performed to form support shielding structures 140s of the second conductivity type extending in a lateral (e.g., X−) direction in the semiconductor structure 106, using the first openings 901o in the first mask pattern 901′ as a mask. For example, dopants of the second conductivity type (e.g., p-type) may be implanted into the exposed portions of the surface S using the mask pattern 901′ as an implantation mask to form support shielding structures 140s extending into the drift region 120 toward the substrate 110. A dose and/or implantation energy of the implantation process(es) 900 may be controlled to form the support shielding structures 140s with desired dopant concentrations and/or depths relative to the surface S (e.g., with higher implantation energies resulting in greater depths). The dopant concentrations of the support shielding structures 140s may be substantially uniform or graded (e.g., stepwise or continuous).

Alternatively, one or more etching processes 900 may be performed using the first mask pattern 901′ as an etching mask to form shield trenches into the exposed portions of the surface S with desired depths, one or more deposition processes may be performed to form a material of the second conductivity type (e.g., p-type) in the shield trenches, and the material of the second conductivity type may be removed from the surface S of the semiconductor structure 106 (e.g., by one or more planarization processes), thereby forming support shielding structures 140s extending into the drift region 120 toward the substrate 110. For example, the drift region 120 may be formed of an n-type material (e.g., SiC), and the support shielding structures 140s may be formed of one or more p-type materials (e.g., p-NiO, p-poly-Si, p-GaN, p-Ga₂O₃).

In FIG. 9D, the mask 901′ is removed, an etching mask layer 902 (e.g., an oxide layer) is formed on the surface S of the semiconductor structure 106, and a patterning layer 92 is formed on the etching mask layer 902. In FIG. 9E, the etching mask layer 902 is patterned using the patterning layer 92 to form a second mask pattern 902′ on the semiconductor structure 106. The second mask pattern 902′ includes respective second openings 902o exposing portions of the surface S of the semiconductor structure 106 between the support shielding structures 140s. Adjacent second openings 902o are spaced apart by a distance or pitch P2 that is different than the distance or pitch P1 between the first openings 901o in the lateral (e.g., Y−) direction.

In FIG. 9F, an etching process 950 is performed to selectively etch the portions of the surface S exposed by the etching mask pattern 902′, thereby forming gate trenches 180 extending into the drift region 120 between and spaced apart from the support shielding structures 140s. Based on the different spacings between the first openings 901o in the first mask pattern 901′ and the second openings 902o in the second mask pattern 902′, the distance (i.e., a first pitch P1) between immediately adjacent pairs of the support shielding structures 140s having one or more of the gate trenches 180 therebetween is different than a distance (i.e., a second pitch P2) between immediately adjacent pairs of the gate trenches 180 having one or more of the support shielding structures 140s therebetween.

Also, the support shielding structures 140s that are between the immediately adjacent pairs of the gate trenches 180 are spaced apart by a distance D1 that is less than the distance P1 between the immediately adjacent pairs of the support shielding structures 140s having one or more of the gate trenches 180 therebetween. Likewise, the gate trenches 180 that are between immediately adjacent pairs of the support shielding structures 140s may be spaced apart by a distance (e.g., D2 in FIG. 3A) that is less than the distance or pitch P2 between the immediately adjacent pairs of the gate trenches 180 having one or more of the support shielding structures 140s therebetween.

While not shown, a third mask pattern may be formed on the semiconductor structure 106 with respective third openings therein that are spaced apart by a third distance or pitch. Using the third openings in the third mask pattern as a mask, one or more ion implantation processes (or etching and deposition processes) may be used to form the bridge shielding structures 140b of the second conductivity type extending in the semiconductor structure 106 in a lateral direction (e.g., the Y-direction) which crosses the direction of extension of the gate trenches 180 and support shielding structures 140s, as shown in the plan views of FIGS. 5A, 6A, 7A, and 8A.

The bridge shielding structures 140b may have respective widths (e.g., W2 in FIG. 6A) that are less than or equal to respective widths (e.g., W1 in FIG. 6A) of the support shielding structures 140s. For example, providing the bridge shielding structures 140b with reduced widths may increase or maximize the available conduction area in the semiconductor structure 106. In some embodiments, by providing the first openings 901o in the first mask pattern 901′ (for forming the support shielding structures 140s) and the third openings in the third mask pattern (for forming the bridge shielding structures 140b) with respective widths that are substantially equal, the support shielding structures 140s may be formed to have the same widths as the bridge shielding structures 140b, which may simplify or ease fabrication operations. Likewise, by providing the first openings 901o and the third openings with respective widths that are substantially equal, the bridge shielding structures 140b and the support shielding structures 140s may be formed with respective depths (in the vertical or Z-direction) that are substantially equal. The first openings 901o (used to form the support shielding structures 140s) and the third openings (used to form the bridge shielding structures 140b) may have respective widths that are between about 0.1 and about 20 microns. Also, the support shielding structures 140s and/or the bridge shielding structures 140b may be formed as a plurality of discrete segments 240 with respective spacings therebetween along the respective direction of extension thereof, as shown in the plan views of FIGS. 6A and 8A, by providing the openings in the respective mask patterns in corresponding segments.

Referring again to FIG. 9F, subsequent implant and/or epitaxial growth processes may be used to form the bottom shielding structures 140a to extend under and at least partially along the bottom surface of the gate trenches 180. Gate oxide layer 182 and gate electrode 184 may be formed in the gate trenches 180, and source contacts 190, intermetal dielectric 186, and metal layer 196 may be subsequently formed provide the device 200a of FIG. 2A or the device 200b of FIG. 2B (where the metal layer(s) 190/196 provide a metal contact 195 that forms a Schottky barrier 194 with portions of the semiconductor structure 106).

While primarily described and illustrated in FIGS. 2A-9F with reference to forming shielding structures 140s and gate trenches 180 having elongated “stripe” shapes (or segmented stripe shapes), it will be understood that the shielding structures 140s and the gate trenches 180 are not so limited, and may be formed in various other shapes. For example, the support shielding structures 140s and/or the gate trenches 180 may have a linear, elliptical, or polygonal shape in plan view.

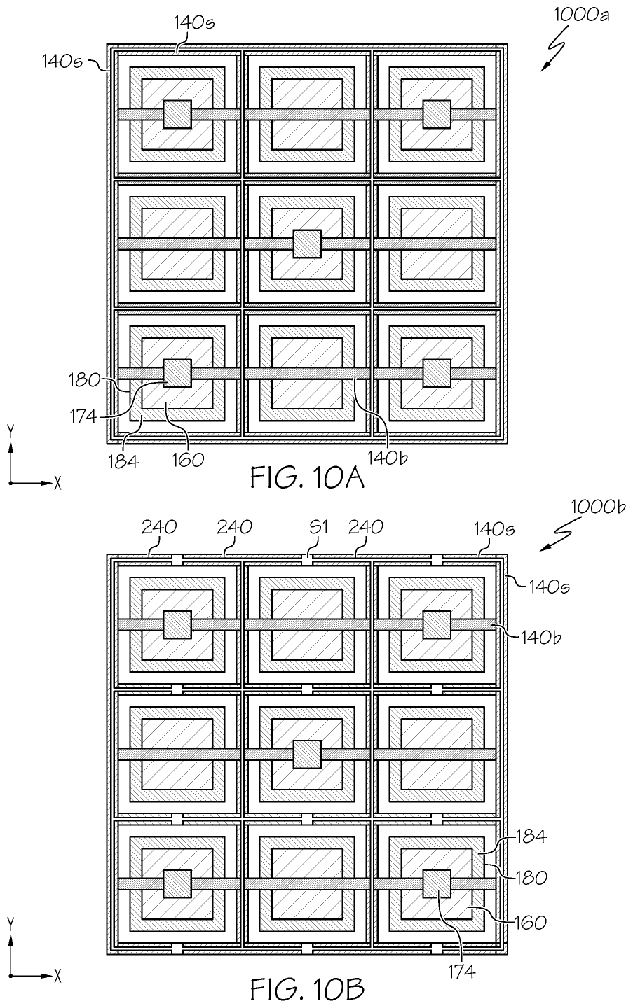

FIGS. 10A and 10B are plan views illustrating patterns of split support shielding structures and segmented split support shielding structures, respectively, in combination with square-shaped trenched gate electrodes 184. In particular, as shown in the example device 1000a of FIG. 10A, the support shielding structures 140s laterally extend in both the X- and Y-directions, parallel to and spaced apart from respective sidewalls of the square-shaped gate trenches 180. The bridge shielding structures 140b laterally extend in the X-direction, intersecting and extending along opposing sidewalls of respective gate trenches 180. In the example device 1000b of FIG. 10B, the support shielding structures 140s include segments 240 with spacings S1 therebetween along the X-direction (as shown) and/or along the Y-direction, while the bridge shielding structures 140b continuously extend along the X-direction. However, it will be understood that the bridge shielding structures 140b may be segmented (in addition to or instead of the support shielding structures 140s) in some embodiments.

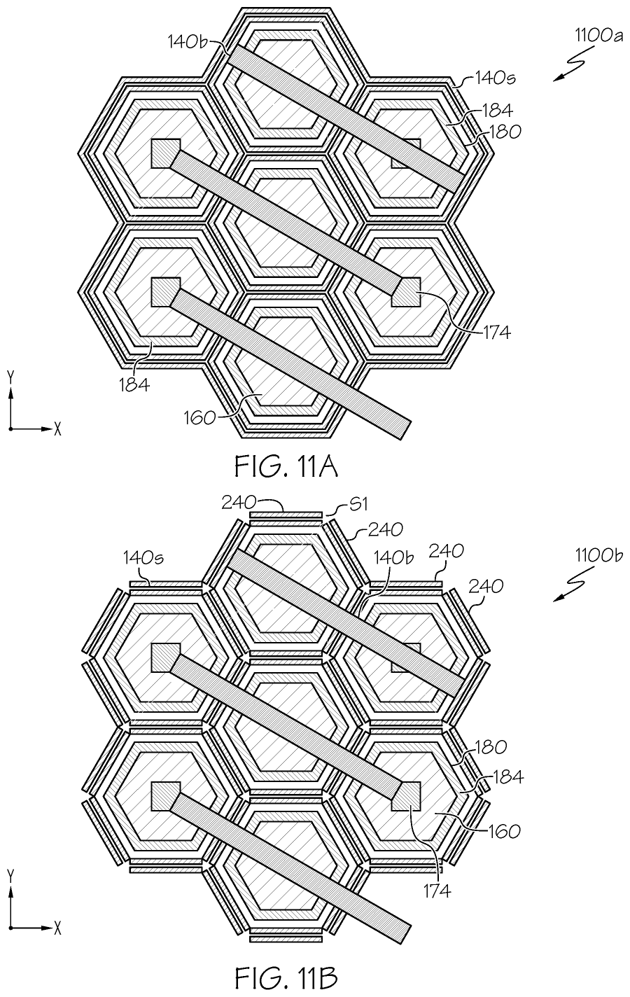

FIGS. 11A and 11B are plan views illustrating patterns of split support shielding structures and segmented split support shielding structures, respectively, in combination with hexagonal-shaped trenched gate electrodes 184. In particular, as shown in the example device 1100a of FIG. 11A, the support shielding structures 140s laterally extend in multiple directions in the X-Y plane, parallel to and spaced apart from respective sidewalls of the hexagonal-shaped gate trenches 180. The bridge shielding structures 140b laterally extend in one direction in the X-Y plane, intersecting and extending along opposing sidewalls of respective gate trenches 180. In the example device 1100b of FIG. 11B, the support shielding structures 140s include segments 240 with spacings S1 therebetween, while the bridge shielding structures 140b continuously extend in the illustrated lateral direction, but it will be understood that the bridge shielding structures 140b may be segmented (in addition to or instead of the support shielding structures 140s) in some embodiments.

The plan views of FIGS. 5A, 6A, 7A, 8A, and 10A-11B discussed above are provided by way of example only, and it will be understood that embodiments of the present disclosure are in no way limited to the arrangements or patterns shown in the examples described herein. That is, embodiments of the present disclosure may include any combination of support shielding structures 140s that are discontinuous or segmented in one or more lateral directions and bridge shielding structures 140b that are continuous in one or more lateral directions (or vice versa), as well as combinations thereof, with linear, elliptical, or polygonal shapes in plan view.

The embodiments described herein thus illustrate various examples of different combinations of shielding structures and gates/gate trenches in accordance with the present disclosure. However, it will be understood that embodiments of the present disclosure may include any and all combinations of the features described herein, and are not limited to the example patterns illustrated. Embodiments of the present invention may be used in trenched gate vertical semiconductor power transistors, including but not limited to MOSFETs, IGBTs, or other power devices where a contact to a shielding region below and/or separated from the well or gate is desired.

In the description above, each example embodiment is described with reference to regions of particular conductivity types. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure (e.g., MOSFET, IGBT, etc.).

The present invention has primarily been discussed above with respect to silicon carbide based power semiconductor devices. It will be appreciated, however, that silicon carbide is used herein as an example and that the devices discussed herein may be formed in any appropriate wide bandgap semiconductor material system. As an example, gallium nitride based semiconductor materials (e.g., gallium nitride, aluminum gallium nitride, etc.) may be used instead of silicon carbide in any of the embodiments described above. More generally, while discussed with reference to silicon carbide devices, embodiments of the present invention are not so limited, and may have applicability to devices formed using other wide bandgap semiconductor materials, for example, gallium nitride, zinc selenide, or any other II-VI or III-V wide bandgap compound semiconductor materials.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Embodiments of the invention are also described with reference to a fabrication operations. It will be appreciated that the steps shown in the fabrication operations need not be performed in the order shown.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments of the invention and, although specific terms are employed, they are used in a generic and descriptive sense only and not for purposes of limitation, the scope of the invention being set forth in the following claims.

1. A power semiconductor device, comprising:
a semiconductor structure comprising a drift region of a first conductivity type;
a plurality of gate trenches respectively comprising sidewalls and a bottom surface therebetween extending in a first direction in the semiconductor structure; and
a plurality of support shielding structures of a second conductivity type extending in the first direction in the semiconductor structure and spaced apart from the sidewalls of the gate trenches,
wherein at least two of the support shielding structures are between immediately adjacent pairs of the gate trenches, or at least two of the gate trenches are between immediately adjacent pairs of the support shielding structures.

2. The power semiconductor device of claim 1, wherein the at least two of the support shielding structures are free of the gate trenches therebetween, and are spaced apart by a first distance that is less than a second distance between pairs of the support shielding structures having one or more of the gate trenches therebetween.

3. The power semiconductor device of claim 1, wherein the at least two of the gate trenches are free of the support shielding structures therebetween, and are spaced apart by a first distance that is less than a second distance between pairs of the gate trenches having one or more of the support shielding structures therebetween.

4. The power semiconductor device of claim 1, further comprising:
a plurality of bottom shielding structures of the second conductivity type extending in the semiconductor structure in the first direction under the gate trenches, respectively; and
a plurality of bridge shielding structures of the second conductivity type extending in the semiconductor structure in a second direction, which crosses the first direction, to contact the bottom shielding structures.

5. The power semiconductor device of claim 4, wherein at least one of the support shielding structures or the bridge shielding structures comprises a plurality of discrete segments with respective spacings therebetween along a direction of extension thereof in the first direction or the second direction, respectively.

6. The power semiconductor device of claim 4, wherein the bridge shielding structures and the support shielding structures have respective widths and/or respective depths that are substantially equal.

7. The power semiconductor device of claim 6, wherein the respective widths are between about 0.1 and about 20 microns.

8. The power semiconductor device of claim 4, wherein the support shielding structures extend into the drift region beyond the bottom shielding structures.

9. The power semiconductor device of claim 1, further comprising:
a metal contact providing a Schottky barrier with the semiconductor structure between a pair of the gate trenches.

10. The power semiconductor device of claim 9, wherein the metal contact comprises a first metal layer that provides ohmic contacts with the support shielding structures and a second metal layer that provides the Schottky barrier with the semiconductor structure.

11. The power semiconductor device of claim 9, wherein the metal contact comprises respective portions that provide the Schottky barrier with the semiconductor structure and ohmic contacts with the support shielding structures.

12. The power semiconductor device of claim 1, wherein a material composition of the support shielding structures is different from that of the drift region.

13. The power semiconductor device of claim 12, wherein the drift region comprises a wide bandgap semiconductor material, and the support shielding structures comprise polysilicon, nickel oxide, gallium nitride, or gallium oxide.

14. The power semiconductor device of claim 1, wherein the support shielding structures and/or the gate trenches have a linear, elliptical, or polygonal shape in plan view.

15. A power semiconductor device, comprising:
a semiconductor structure comprising a drift region of a first conductivity type;
a plurality of gate trenches extending in a first direction in the semiconductor structure and spaced apart in a second direction; and
a plurality of support shielding structures of a second conductivity type extending in the first direction in the semiconductor structure and spaced apart from respective sidewalls of the gate trenches in the second direction,
wherein immediately adjacent pairs of the support shielding structures having one or more of the gate trenches therebetween are spaced apart at a first pitch, and immediately adjacent pairs of the gate trenches having one or more of the support shielding structures therebetween are spaced apart at a second pitch that is different than the first pitch.

16. The power semiconductor device of claim 15, wherein at least two of the support shielding structures are free of the gate trenches therebetween and are spaced apart by a first distance that is less than the first pitch.

17. The power semiconductor device of claim 15, wherein at least two of the gate trenches are free of the support shielding structures therebetween and are spaced apart by a second distance that is less than the second pitch.

18. The power semiconductor device of claim 15, further comprising:
a plurality of bottom shielding structures of the second conductivity type extending in the semiconductor structure in the first direction under the gate trenches, respectively.

19. The power semiconductor device of claim 18, further comprising:
a plurality of bridge shielding structures of the second conductivity type extending in the semiconductor structure in a second direction, which crosses the first direction, to contact the bottom shielding structures.

20.-21. (canceled)

22. The power semiconductor device of claim 15, further comprising:
a metal contact providing a Schottky barrier with the semiconductor structure between a pair of the gate trenches.

23-24. (canceled)

25. A power semiconductor device, comprising:
a semiconductor structure comprising a drift region of a first conductivity type;
first and second gate trenches extending in a first direction in the semiconductor structure;
first and second support shielding structures of a second conductivity type extending in the first direction in the semiconductor structure and spaced apart from sidewalls of the first and second gate trenches; and
a metal contact providing a Schottky barrier with the semiconductor structure between the first and second gate trenches.

26. The power semiconductor device of claim 25, wherein the metal contact comprises a first metal layer that provides ohmic contacts with the first and second support shielding structures and a second metal layer that provides the Schottky barrier with the semiconductor structure.

27. The power semiconductor device of claim 25, wherein the metal contact comprises a continuous layer having respective portions that provide the Schottky barrier with the semiconductor structure and ohmic contacts with the first and second support shielding structures.

28. The power semiconductor device of claim 25, wherein the first and second support shielding structures are between the first and second gate trenches.

29. The power semiconductor device of claim 25, wherein the first and second gate trenches are between the first and second support shielding structures.

30. The power semiconductor device of claim 25, further comprising:
first and second bottom shielding structures of the second conductivity type extending in the semiconductor structure in the first direction under the first and second gate trenches, respectively; and
at least one bridge shielding structure of the second conductivity type extending in the semiconductor structure in a second direction, which crosses the first direction, to contact the first and second bottom shielding structures.

31. (canceled)

32. The power semiconductor device of claim 30, wherein the at least one bridge shielding structure and the first and second support shielding structures have respective widths and/or respective depths that are substantially equal.

33. A method of fabricating a power semiconductor device, the method comprising:
providing a semiconductor structure comprising a drift region of a first conductivity type;
forming a first mask pattern on the semiconductor structure, the first mask pattern comprising respective first openings therein that are spaced apart by a first distance,
forming support shielding structures of a second conductivity type extending in a first direction in the semiconductor structure using the first openings in the first mask pattern;
forming a second mask pattern on the semiconductor structure, the second mask pattern comprising respective second openings therein that are spaced apart by a second distance that is different than the first distance; and
forming gate trenches extending in the first direction in the semiconductor structure using the second openings in the second mask pattern, wherein the gate trenches are spaced apart from the support shielding structures.

34.-45. (canceled)
